(19) United States
(12) Patent Application Publication
(10) Pub. No.: US 2024/0395577 A1
(43) Pub. Date: Nov. 28, 2024

(54) MICRO-LED DISPLAY MANUFACTURING APPARATUS

(71) Applicant: LG ELECTRONICS INC., Seoul (KR)

(72) Inventors: Junghun RHO, Seoul (KR); Imdeok JUNG, Seoul (KR); Bongwoon CHOI, Seoul (KR)

(73) Assignee: LG ELECTRONICS INC., Seoul (KR)

(21) Appl. No.: 18/695,403

(22) PCT Filed: Oct. 18, 2021
(86) PCT No.: PCT/KR2021/014445

§ 371 Date: Mar. 26, 2024

(51) Int. Cl. H01L 21/67; H01L 21/687; H01L 25/16

(52) U.S. Cl. CPC H01L 21/67144; H01L 21/68785; H01L 25/167

(57) ABSTRACT

The present embodiment comprises: a chip tray accommodated in a chamber; a chip bath in which a plurality of LED chips are accommodated; a magnet head which adsorbs/isolates an LED chip by a magnetic force; and a head transport mechanism which transports the magnet head to a first position of the chip bath and a second position of the chip tray, wherein the magnet head comprises: a magnet housing in which a magnet is accommodated; a moving-up/down member which moves up and down the magnet housing; a driving source which moves up and down the moving-up/down member; and a glass to/from which an LED chip is adsorbed or isolated.

### TECHNICAL FIELD

The present disclosure relates to an apparatus for manufacturing a micro-light emitting diode (LED) display, and more particularly, to a micro-LED display manufacturing apparatus for manufacturing a micro-LED display.

### BACKGROUND ART

Recently, displays having excellent characteristics such as a thin shape and flexibility have been developed in the display technology field. On the other hand, a liquid crystal display (LCD) and active-matrix organic light emitting diodes (AMOLED) are representative of main displays that are commonly used now.

However, the LCD has a problem that a response time is not short and it is difficult to implement flexibility and AMOLED has a defect that the lifespan is short and the yield is not good.

Meanwhile, a light emitting diode (LED), which is a well-known semiconductor device that converts a current into light, has been used as a light source for displaying images in electronic devices including information devices together with a green LED based on GaP: N since a red LED using a GaAsP compound semiconductor was commercialized in 1962. Accordingly, a plan that solves the problems by implementing a display using the semiconductor LED may be proposed. Such an LED has the advantage of a long lifespan, low power consumption, an excellent initial driving characteristic, high vibration resistance, etc, as compared with a filament-based light emitting element.

Recently, micro-LEDs (μLEDs) with a size of 10 to 100 micrometers (μm), which are about 1/10^{th} the length and 1/100^{th} the area of general light emitting diode (LED) chips, have been gradually used.

Such a micro-LED (μLED) has an advantage of a high reaction speed, low power, and high luminance are supported compared to an existing LED, and when applied to a display, the micro-LED is not broken when being bent.

In the case of a display to which the micro-LED is applied, a light emission inspection may be performed to test light emission of a micro-LED after transferring the micro LED to a substrate or an interposer.

### DISCLOSURE

### Technical Problem

An object of the present disclosure is to a micro-light emitting diode (LED) display manufacturing apparatus for rapidly and accurately transferring a large amount of LED chips.

### Technical Solution

In an aspect of the present disclosure, an apparatus for manufacturing a micro light emitting diode (LED) display comprises a chip tray accommodated in a chamber, a chip bath accommodating a plurality of LED chips therein, a magnet head configured to adsorb/separate the LED chip by magnetic force, and a head transfer device configured to move the magnet head to a first position of the chip bath and a second position of the chip tray, wherein the magnet head comprises a magnet housing accommodating a magnet therein, an elevating member configured to elevate the magnet housing, a driving source configured to elevate the elevating member, and a glass to and from which the LED chip is adsorbed and separated.

The magnet head may comprise a head housing with a space formed therein to accommodate the magnet housing and the elevating member are accommodated, and the glass may be located on a lower surface of the head housing.

The driving source may be located on an upper surface of the head housing.

The elevating member may comprise a fixed body fixed to an upper surface of the magnet housing, an elevating shaft fixed to an upper surface of the fixed body, and the head housing may comprise a through hole formed therein through which the elevating shaft passes.

The chip bath may be formed in the chamber.

The apparatus may further comprise a chip tray supporter located apart from the chip bath in the chamber and having an accommodation body formed therein to accommodate the chip tray.

The chip tray supporter may comprise a connection body connected to the accommodation body, and the connection body may surround an inner lateral surface, an upper end, and an outer lateral surface of an edge of the chamber.

The plurality of chip tray supporters may be located apart from each other.

The apparatus may further comprise a driving device configured to move the chip tray supporter in a longitudinal direction of the chamber.

The apparatus may further comprise a table on which the chamber is seated, wherein the driving device and the head transfer device may be located on the table.

### Advantageous Effects

According to an embodiment of the present disclosure, a magnet head may rapidly transfer a plurality of light emitting diode (LED) chips accommodated in a chip tray to the chip tray with high reliability.

The LED chips may be adsorbed to a glass located on a lower surface of a head housing, thereby minimizing damage to a magnet housing or a head housing.

A chip bath may be formed in a chamber together with the chip tray, and thus a transfer distance of the magnet head may be minimized.

The chip tray may be seated on the chip tray supporter, and thus damage to the chip tray and the chamber may be minimized, and the lifespan of the chamber may be prolonged.

### DESCRIPTION OF DRAWINGS

FIG. 1 is a conceptual view showing an embodiment of a display using a semiconductor light emitting diode of the present disclosure.

FIG. 2 is a partial enlarged view of the portion A of FIG. 1 and FIGS. 3A and 3B are cross-sectional views taken along line B-B and C-C of FIG. 2.

FIG. 4 is a conceptual view showing a flip-chip type semiconductor light emitting diode of FIG. 3.

FIGS. 5A to 5C are conceptual views showing various types that implement colors in relation to a flip-chip type semiconductor light emitting diode.

FIG. 6 shows cross-sectional views illustrating a method of manufacturing a display using a semiconductor light emitting diode of the present disclosure.

FIG. 7 is a perspective view showing another embodiment of a display using a semiconductor light emitting diode of the present disclosure.

FIG. 8 is a cross-sectional view taken along line D-D of FIG. 7.

FIG. 9 is a conceptual view showing a vertical semiconductor light emitting diode of FIG. 8.

FIG. 10 is a perspective view of a micro-light emitting diode (LED) display manufacturing apparatus according to the present embodiment.

FIG. 11 is a cross-sectional view illustrating the inside of a magnet head according to the present embodiment.

FIG. 12 is a side view showing a driving device according to the present embodiment.

### BEST MODE

Hereinafter, a detailed embodiment of the present disclosure will be described in detail with reference to the drawings.

Hereafter, embodiments of the present disclosure will be described in detail with reference to the accompanying drawings and the same or similar components are given the same reference numerals regardless of the numbers of figures and are not repeatedly described. Terms “module” and “unit” that are used for components in the following description are used only for the convenience of description without having discriminate meanings or functions. In the following description, if it is decided that the detailed description of known technologies related to the present disclosure makes the subject matter of the embodiments described herein unclear, the detailed description is omitted. Further, it should be noted that the accompanying drawings are provided only for easy understanding of the embodiments disclosed herein and the spirit of the present disclosure should not be construed as being limited to the accompanying drawings.

When an element such as a layer, a region, or a substrate is referred to as being “on,” another element, it may be directly on the other element, or an intervening element may be present therebetween.

A display described herein may comprise a mobile phone, a smart phone, a laptop computer, a digital broadcasting terminal, a PDA (personal digital assistants), a PMP (portable multimedia player), a navigation, a slate PC, a tablet PC, a ultra book, a digital TV, a desktop computer, etc. However, it would be easily understood by those skilled in the art that the configuration according to embodiments described here may be applied to devices that may be equipped with a display, even if the devices are new types of products that will be developed in future.

Before an assembly apparatus for assembling a semiconductor light emitting diode to a display panel (substrate) according to an embodiment of the present disclosure is described, a semiconductor light emitting diode and a display using the semiconductor light emitting diode are described.

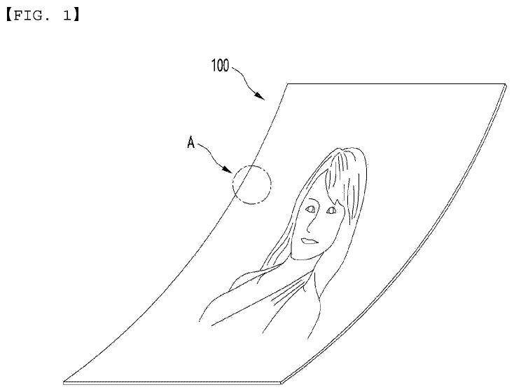

FIG. 1 is a conceptual diagram showing an embodiment of a display using a semiconductor light emitting diode of the present disclosure.

Referring to the figure, information that is processed by a controller of a display 100 may be displayed using a flexible display.

The flexible display comprises displays that may be bent, curved, twisted, folded, and rolled by external force. For example, the flexible display may be a display that is manufactured on a thin and flexible substrate, which may be bent, curved, folded, or rolled like paper, while maintaining the display characteristics of existing flat panel display.

In a state in which the flexible display is not bent (e.g., in which the flexible display has an infinite radius of curvature, which is referred to as a ‘first state’ hereafter), the display region of the flexible display becomes a flat surface. In a state in which the flexible display is bent from the first state by external force (e.g., in which the flexible display has a finite radius of curvature, which is referred to as a ‘second state’ hereafter), the display region may be a curved surface. As shown in the figure, the information that is displayed in the second state may be visual information that is output on the curved surface. Such visual information is implemented by individual control of light emission of sub-pixels disposed in a matrix type. The sub-pixel means a minimum unit for implementing one color.

The sub-pixels of the flexible display may be implemented by a semiconductor light emitting diode. A light emitting diode (LED) that is a kind of semiconductor light emitting diode converting a current into light is exemplified in the present disclosure. The light emitting diode is formed in a small size, so it may function as a sub-pixel even in the second state.

Hereafter, a flexible display implemented using the light emitting diode is described in more detail with reference to drawings.

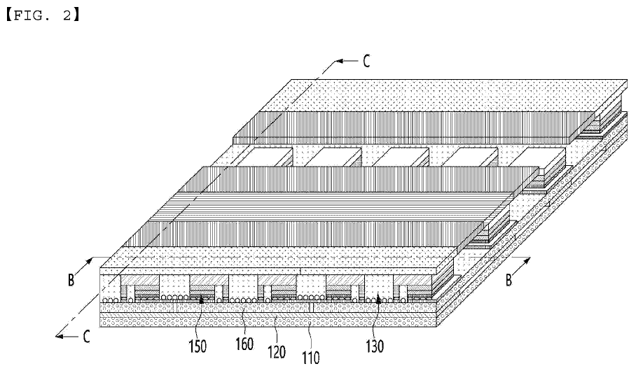

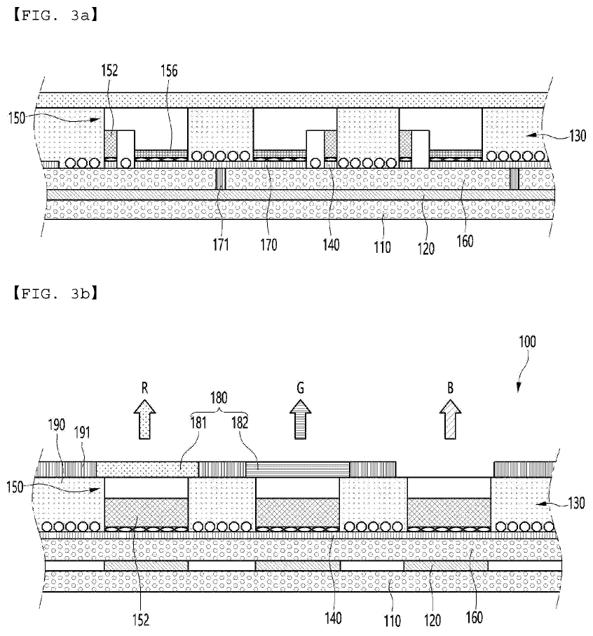

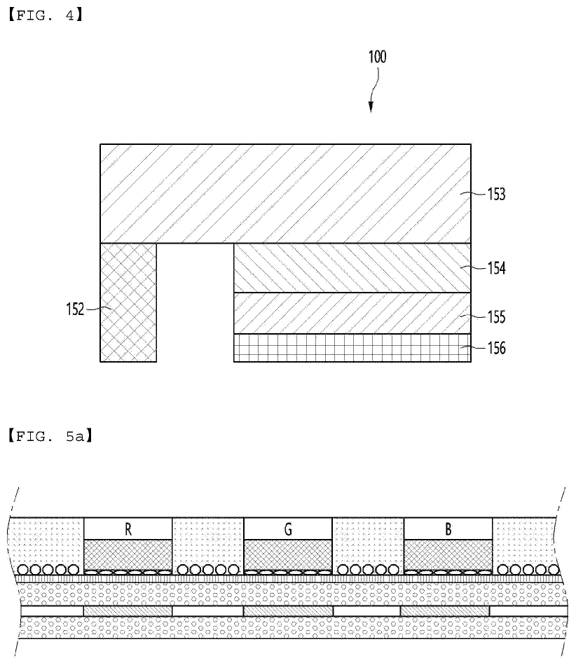

FIG. 2 is a partial enlarged view of the portion A of FIG. 1, FIGS. 3A and 3B are cross-sectional views taken along lines B-B and C-C of FIG. 2, FIG. 4 is a conceptual view showing a flip-chip type semiconductor light emitting diode of FIG. 3A, and FIGS. 5A to 5C are conceptual views showing various types that implement colors in relation to a flip-chip type semiconductor light emitting diode.

According to FIGS. 2, 3A, and 3B, as a display 100 using a semiconductor light emitting diode, a display 100 using a passive matrix (PM) type of semiconductor light emitting diode is exemplified. However, examples to be described hereafter may be applied also to an active matrix (AM) type of semiconductor light emitting diode.

The display 100 comprises a first substrate 110, a first electrode 120, a conductive adhesive layer 130, a second electrode 140, and a plurality of semiconductor light emitting diodes 150.

The substrate 110 may be a flexible substrate. For example, the substrate 110 may comprise glass or polyimide (PI) to implement a flexible display. Further, any materials may be used as long as they have insulation and flexibility such as polyethylene naphthalate (PEN) and polyethylene terephthalate (PET). Further, the substrate 110 may be made of any one of a transparent material or an opaque material.

The substrate 110 may be a wiring board on which the first electrode 120 is disposed, so the first electrode 120 may be positioned on the substrate 110

According to the drawings, an insulating layer 160 may be disposed over the substrate 110 on which the first electrode 120 is positioned, and an auxiliary electrode 170 may be positioned on the insulating layer 160. In this case, the state in which the insulating layer 160 is stacked on the substrate 110 may be one wiring board. In more detail, the insulating layer 160 may be made of an insulating and flexible material, such as PI (Polyimide), PET, and PEN, integrally with the substrate 110, thereby forming one substrate.

The auxiliary electrode 170, which is an electrode electrically connecting the semiconductor light emitting diodes 150, is positioned on the insulating layer 160 and disposed to correspond to the first electrode 120. For example, the auxiliary electrode 170 has a dot shape and may be electrically connected with the first electrode 120 by electrode holes 171 formed through the insulating layer 160. The electrode hole 171 may be formed by filing a via hole with a conductive material.

Referring to the figures, the conductive adhesive layer 130 is formed on a surface of the insulating layer 160, but the present disclosure is not necessarily limited thereto. For example, a structure, in which a layer performing a specific function is formed between the insulating layer 160 and the conductive adhesive layer 130 or the conductive adhesive layer 130 is disposed on the substrate 110 without the insulating layer 160, is possible. In the structure in which the conductive adhesive layer 130 is disposed on the substrate 110, the conductive adhesive layer 130 may function as an insulating layer.

The conductive adhesive layer 130 may be a layer having an adhesive property and conductivity, and to this end, a substance having conductivity and a substance having an adhesive property may be mixed in the conductive adhesive layer 130. Further, the conductive adhesive layer 130 has ductility, so it enables the flexible function of the display.

As an example of this case, the conductive adhesive layer 130 may be an anisotropy conductive film (ACF), an anisotropy conductive paste, and a solution containing conductive particles. The conductive adhesive layer 130 may be configured as a layer that allows for electrical connection in a Z direction passing through the thickness, but has electrical insulation in the horizontal X-Y direction. Accordingly, the conductive adhesive layer 130 may be referred to as a Z-axial conductive layer (however, hereafter, referred to as a ‘conductive adhesive layer’).

The anisotropic conductive film is a film in which an anisotropic conductive medium is mixed in an insulating base member, and only a specific portion is given conductivity by the anisotropic conductive medium when heat and pressure are applied. It is assumed in the following description that heat and pressure are applied to the anisotropic conductive film, but other methods are also possible so that the anisotropic conductive film partially has conductivity. These methods, for example, may be a case of applying only any one of heat and pressure or a case of UV curing.

Further, the anisotropic conductive medium, for example, may be a conductive ball or a conductive particle. According to the figures, in this embodiment, the anisotropic conductive film is a film in which conductive balls are mixed in an insulating base member, and only a specific portion is given conductivity by the conductive balls when heat and pressure are applied. The anisotropic conductive film may be in a state in which a plurality of particles coated with an insulating film made of a polymer material is contained in a core made of a conductive substance, and in this case, when heat and pressure are applied a portion, the insulating film is broken at the portion and the portion is given conductivity by the core. In this case, the shape of the core is deformed, so layers that are in contact with each other in the thickness direction of the film may be formed. As a more detailed example, heat and pressure are applied throughout the anisotropic conductive film and Z-axial electrical connection is partially formed by the height difference of an object that is bonded by the anisotropic conductive film.

As another example, the anisotropic conductive film may be in a state in which a plurality of particles coated with a conductive substance is contained in an insulating core. In this case, when heat and pressure are applied to a portion, the conductive substance at the portion is deformed (gets scored and sticks), so the portion is given conductivity in the thickness direction of the film. As another example, the conductive substance may pass through the insulating base member in the Z-axial direction to show conductivity in the thickness direction of the film. In this case, the conductive substance may have a pointed end.

According to the figures, the anisotropic conductive film may be a fixed array ACF in which conductive balls are inserted in a surface of an insulating base member. In more detail, the insulating base member is made of an adhesive substance, the conductive balls are concentrated at the bottom of the insulating base member, and when heat and pressure are applied to the base member, the base member is deformed with the conductive balls, thereby being given vertical conductivity.

However, the present disclosure is not limited thereto, and the anisotropic conductive film may be configured in a type in which conductive balls are randomly mixed in an insulating base member or a type in which a plurality of layers is provided and conductive balls are disposed in any one layer (double-ACF).

The anisotropic conductive paste is formed by combining a paste and conductive balls, and may be a paste in which conductive balls are mixed in an insulating and adhesive base substance. Further, the solution containing conductive particles may be a solution containing conductive particles or nano particles.

Referring to figures again, the second electrode 140 is spaced apart from the auxiliary electrode 170 and positioned on the insulating layer 160. That is, the conductive adhesive layer 130 is disposed on the insulating layer 160 on which the auxiliary electrode 170 and the second electrode 140 are positioned.

When the conductive adhesive layer 130 is formed in a state in which the auxiliary electrode 170 and the second electrode 140 are positioned on the insulating layer 160, and then the semiconductor light emitting diode 150 is connected in a flip-chip type by applying heat and pressure, the semiconductor light emitting diode 150 is electrically connected with the first electrode 120 and the second electrode 140.

Referring to FIG. 4, the semiconductor light emitting diode may be a flip-chip type light emitting diode.

For example, the semiconductor light emitting diode comprises a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 horizontally spaced apart from the p-type electrode 156 on the n-type semiconductor layer 153. In this case, the p-type electrode 156 may be electrically connected with the auxiliary electrode 170 by the conductive adhesive layer 130, and the n-type electrode 152 may be electrically connected with the second electrode 140.

Referring to FIGS. 2, 3A, and 3B again, the auxiliary electrode 170 is elongated in one direction and at least one auxiliary electrode may be electrically connected with a plurality of semiconductor light emitting diodes 150. For example, the p-type electrodes of semiconductor light emitting diodes at left and right sides from an auxiliary electrode may be electrically connected with one auxiliary electrode.

In more detail, the semiconductor light emitting diode 150 is pressed into the conductive adhesive layer 130 by heat and pressure, so only the portion between the p-type electrode 156 of the semiconductor light emitting diode 150 and the auxiliary electrode 170 and the portion between the n-type electrode 152 of the semiconductor light emitting diode 150 and the second electrode 140 have conductivity, and the other portions do not have conductivity because the semiconductor light emitting diode is pressed inside. As described above, the conductive adhesive layer 130 not only couples, but also electrically connects the portion between the semiconductor light emitting diode 150 and the auxiliary electrode 170 and the portion between the semiconductor light emitting diode 150 and the second electrode 140.

Further, the plurality of semiconductor light emitting diodes 150 constitutes a light emitting diode array, and a fluorescent layer 180 is formed on the light emitting diode array.

The light emitting diode array may comprise a plurality of semiconductor light emitting diodes having different own luminance values. Each of the semiconductor light emitting diode 150 constitutes a sub-pixel and is electrically connected to the first electrode 120. For example, the first electrode 120 may be a plurality of pieces, the semiconductor light emitting diodes, for example, may be arranged in several lines, and the semiconductor light emitting diodes in each line may be electrically connected to any one of the plurality of first electrodes.

Further, since the semiconductor light emitting diodes are connected in a flip-chip type, it is possible to use grown semiconductor light emitting diodes for a transparent dielectric substrate. Further, the semiconductor light emitting diodes, for example, may be nitride semiconductor light emitting diodes. Since the semiconductor light emitting diode 150 has excellent luminance, it may constitute an individual sub-pixel even in a small size.

According to the figures, a separation wall 190 may be formed between the semiconductor light emitting diodes 150. In this case, the separation wall 190 may serve to separate individual sub-pixels and may be formed integrally with the conductive adhesive layer 130. For example, the semiconductor light emitting diodes 150 are inserted in the anisotropic conductive film, the base member of the anisotropic conductive film may form the separation wall.

Further, when the base member of the anisotropic conductive film is black, the separation wall 190 may have a reflective characteristic and the contrast may be increased even without a discrete black insulator.

As another example, a reflective separation wall may be provided as the separation wall 190. In this case, the separation wall 190 may comprise a black or white insulator, depending on the object of the display. When a separation wall of a white insulator is used, there may be an effect of increasing reflectivity, and when a separation wall of a black insulator, it is possible to have a reflective characteristic and increase contrast.

The fluorescent layer 180 may be positioned on the outer side of the semiconductor light emitting diode 150. For example, the semiconductor light emitting diode 150 is a blue semiconductor light emitting diode that emits blue light (B), and the fluorescent layer 180 performs a function of converting the blue light (B) into a color of a sub-pixel. The fluorescent layer 180 may be a red fluorescent body 181 or a green fluorescent body 182 that constitutes an individual pixel.

That is, the red fluorescent body 181 that may convert blue light into red light (R) may be stacked on a blue semiconductor light emitting diode at a position where a red sub-pixel is formed, and the green fluorescent body 182 that may convert blue light into green light (G) may be stacked on a blue semiconductor light emitting diode at a position where a green sub-pixel is formed. Further, only a blue semiconductor light emitting diode may be independently used a portion forming a blue sub-pixel. In this case, red (R), green (G), and blue (B) sub-pixels may form one pixel. In more detail, a fluorescent body having one color may be stacked along each line of the first electrode 120. Accordingly, in the first electrode 120, one line may be an electrode that controls one color. That is, red (R), green (G), and blue (B) may be sequentially disposed along the second electrode 140, whereby a sub-pixel may be implemented.

However, the present disclosure is not necessarily limited thereto, and red (R), green (G), and blue (B) sub-pixels may be implemented by combining the semiconductor light emitting diode 150 and a quantum dot (QD) instead of a fluorescent body.

Further, a black matrix 191 may be disposed between each of fluorescent bodies to improve contrast. That is, the black matrix 191 may improve the contrast of light and darkness.

However, the present disclosure is not necessarily limited thereto and another structure may be applied to implement blue, red, and green.

Referring to FIG. 5A, the semiconductor light emitting diodes 150 each may be implemented as a high-power light emitting diodes in which gallium nitride (GaN) is comprised as a main component and indium (In) and/or aluminum (Al) is added to emit various colors of light including blue.

In this case, the semiconductor light emitting diodes 150 may be red, green, and blue semiconductor light emitting diodes to from sub-pixels respectively. For example, red, green, and blue semiconductor light emitting diodes (R, G, B) are alternately disposed, and sub-pixels of red, green, and blue constitute one pixel by the red, green, and blue semiconductor light emitting diodes, whereby a full-color display may be implemented.

Referring to FIG. 5B, the semiconductor light emitting diode may have white light emitting diodes (W) each having a yellow fluorescent layer. In this case, in order to form a sub-pixel, a red fluorescent layer 181, a green fluorescent layer 182, and a blue fluorescent layer 183 may be disposed on the white light emitting diode (W). Further, a sub-pixel may be formed using a color filter in which red, green, and blue are repeated, on the white light emitting diode (W).

Referring to FIG. 5C, a structure in which a red fluorescent layer 181, a green fluorescent layer 182, and a blue fluorescent layer 183 are disposed on an ultraviolet light emitting diode (UV) may be possible. As described above, a semiconductor light emitting diode may be used in the entire region including not only the visual light, but also ultraviolet light (UV), and may be expanded in the type of a semiconductor light emitting diode that may use ultraviolet light (UV) as an excitation source of an upper fluorescent body.

Referring to this embodiment again, the semiconductor light emitting diode 150 is positioned on the conductive adhesive layer 130, thereby constituting a sub-pixel in the display. Since the semiconductor light emitting diode 150 has excellent luminance, it may constitute an individual sub-pixel even in a small size. The individual semiconductor light emitting diode 150 may have a size with one side of 80 μm or less and may be a rectangular or a square diode. When it is a rectangle, the size may be 20×80 μm or less.

Further, even using a square semiconductor light emitting diode 150 having one side length of 10 μm as a sub-pixel, sufficient brightness for forming a display is shown. Accordingly, for example, in a case in which the size of a sub-pixel is a rectangular pixel having one side of 600 μm and the other one side of 300 μm, the distance of a semiconductor light emitting diode is relatively sufficiently large. Accordingly, in this case, it is possible to implement a flexible display having high quality over HD quality.

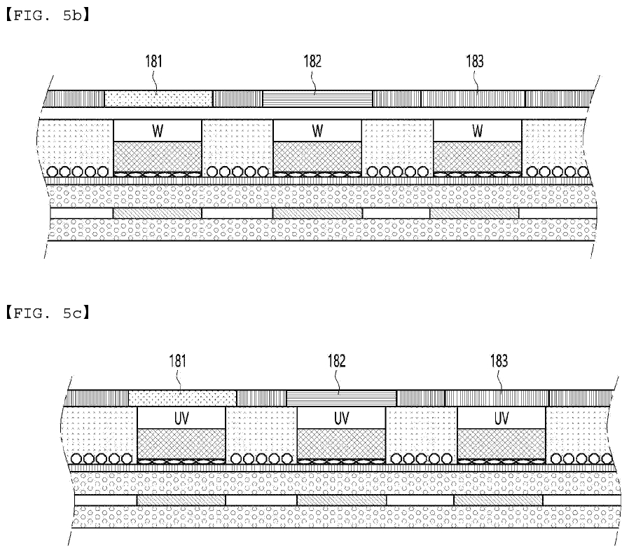

The display using the semiconductor light emitting diode described above may be manufactured by a new type of manufacturing method. Hereafter, this manufacturing method is described with reference to FIG. 6.

FIG. 6 shows cross-sectional views illustrating a method of manufacturing a display using a semiconductor light emitting diode of the present disclosure.

Referring to this figure, first, the conductive adhesive layer 130 is formed on the insulating layer 160 on which the auxiliary electrode 170 and the second electrode 140 are positioned. The insulating layer 160 is stacked on the first substrate 110, thereby forming one substrate (wiring board). Further, the first electrode 120, the auxiliary electrode 170, and the second electrode 140 are disposed on the wiring board. In this case, the first electrode 120 and the second electrode 140 may be disposed perpendicular to each other. Further, in order to implement a flexible display, the first substrate 110 and the insulating layer 160 each may comprise glass or polyimide (PI).

The conductive adhesive layer 130, for example, may be implemented by an anisotropic conductive film, and to this end, an anisotropic conductive film may be applied to a substrate on which the insulating layer 160 is positioned.

Next, a second substrate 112 on which a plurality of semiconductor light emitting diodes 150, which correspond to the positions of the auxiliary electrodes 170 and the second electrodes 140 and constitute individual pixels, is positioned is disposed such that the semiconductor light emitting diodes 150 face the auxiliary electrodes 170 and the second electrodes 140.

In this case, the second substrate 112, which is a growing substrate for growing the semiconductor light emitting diodes 150, may be a spire substrate or a silicon substrate.

The semiconductor light emitting diodes have a gap and a size that may form a display when they are formed in a wafer unit, so they may be effectively used for a display.

Next, the wiring board and the second substrate 112 are thermally pressed. For example, the wiring board and the second substrate 112 may be thermally pressed using an ACF press head. The wiring board and the second substrate 112 are bonded by the thermal pressing. Only the portions among the semiconductor light emitting diode 150, the auxiliary electrode 170, and the second electrode 140 have conductivity by the characteristics of an anisotropic conductive film having conductivity by thermal pressing, so the electrodes and the semiconductor light emitting diodes 150 may be electrically connected. In this case, the semiconductor light 150 are inserted in the anisotropic conductive film, so separation walls may be formed between the semiconductor light emitting diodes 150.

Next, the second substrate 112 is removed. For example, it is possible to remove the second substrate 112 using Laser Lift-off (LLO) or Chemical Lift-off (CLO).

Finally, the semiconductor light emitting diodes 150 are exposed to the outside by removing the second substrate 112. If necessary, it is possible to form a transparent insulating layer (not shown) by coating the top of the wiring board, to which the semiconductor light emitting diodes 150 are coupled, with silicon oxide (SiOx), etc.

Further, a step of forming a fluorescent layer on a surface of the semiconductor light emitting diode 150 may be further comprised. For example, the semiconductor light emitting diode 150 may be a blue semiconductor light emitting diode that emits blue light (B), and a red fluorescent body or a green fluorescent body for converting the blue light (B) into the light of a sub-pixel may form a layer on a surface of the blue semiconductor light emitting diode.

The manufacturing method or structure of the display using a semiconductor light emitting diode described above may be modified in various ways. As an example, a vertical semiconductor light emitting diode may also be applied to the display described above. Hereafter, a vertical structure is described with reference to FIGS. 5 and 6.

Further, in the modification or embodiment to be described hereafter, the same or similar components are given the same or similar reference numerals, and the above description is referred to for the description.

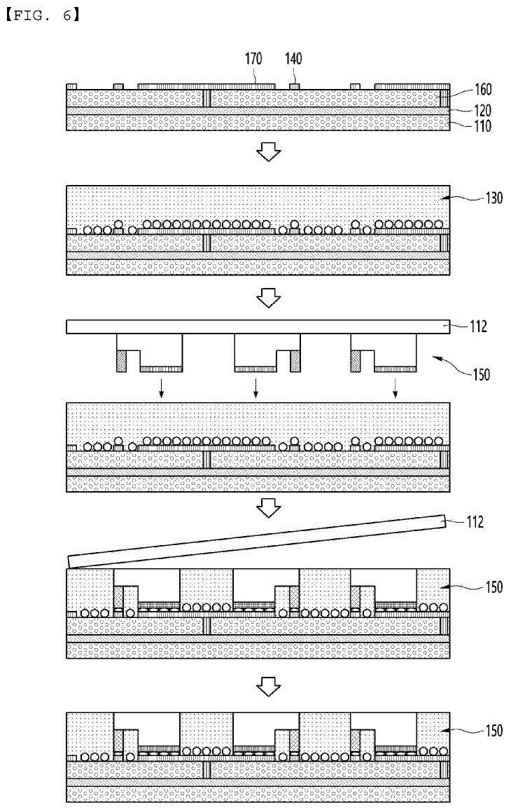

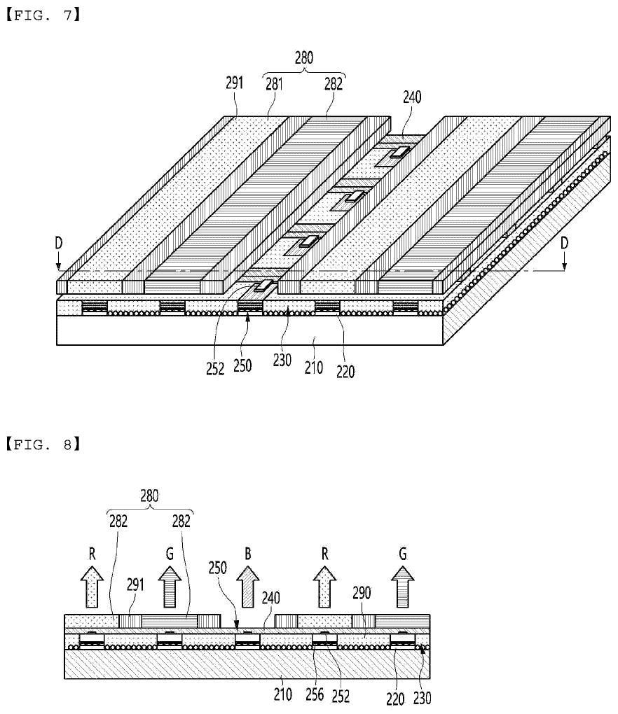

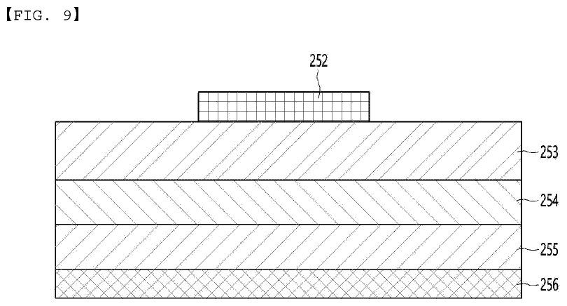

FIG. 7 is a perspective view showing another embodiment of a display using a semiconductor light emitting diode of the present disclosure, FIG. 8 is a cross-sectional view taken along line D-D of FIG. 7, and FIG. 9 is a conceptual view showing a vertical semiconductor light emitting diode of FIG. 8.

Referring to these figures, the display may be a display that uses passive matrix (PM) type of vertical semiconductor light emitting diodes.

The display comprises a substrate 210, a first electrode 220, a conductive adhesive layer 230, a second electrode 240, and a plurality of semiconductor light emitting diodes 250.

The substrate 210, which is a wiring board on which the first electrode 220 is disposed, may comprise polyimide (PI) to implement a flexible display. Further, any materials may be used as long as they have insulation and flexibility.

The first electrode 220 is positioned on the substrate 210 and may be formed in a bar shape that is long in one direction. The first electrode 220 may be configured to function as a data electrode.

The conductive adhesive layer 230 is formed on the substrate 210 on which the first electrode 220 is positioned. Like a display to which flip-chip type light emitting diodes are applied, the conductive adhesive layer 230 may be an anisotropy conductive film (ACF), an anisotropy conductive paste, and a solution including conductive particles. However, in this embodiment, a case in which the conductive adhesive layer 230 is implemented by an anisotropic conductive film is exemplified.

An isotropic conductive film is positioned in a state in which the first electrode 220 is positioned on the substrate 210 and then the semiconductor light emitting diode 250 is connected by applying heat and pressure, the semiconductor light emitting diode 250 is electrically connected with the first electrode 220. In this case, it is preferable that the semiconductor light emitting diode 250 is disposed to be positioned on the first electrode 220.

The electrical connection, as described above, is generated because when heat and pressure are applied, the anisotropic conductive film partially has conductivity in the thickness direction. Accordingly, the anisotropic conductive film is divided into a portion having conductivity in the thickness direction and a portion not having conductivity in the thickness direction.

Further, since the anisotropic conductive film contains an adhesive component, the conductive adhesive layer 230 implements not only electrical connection, but also mechanical coupling between the semiconductor light emitting diode 250 and the first electrode 220.

As described above, the semiconductor light emitting diode 250 is positioned on the conductive adhesive layer 230, whereby it configures an individual pixel in the display. Since the semiconductor light emitting diode 250 has excellent luminance, it may constitute an individual sub-pixel even in a small size. The individual semiconductor light emitting diode 250 may have a size with one side of 80 μm or less and may be a rectangular or a square diode. When it is a rectangle, the size may be 20×80 μm or less.

The semiconductor light emitting diode 250 may be a vertical structure.

A plurality of second electrodes 240 disposed across the length direction of the first electrode 220 and electrically connected with the vertical semiconductor light emitting diodes 250 is positioned between the vertical semiconductor light emitting diodes.

Referring to FIG. 9, the vertical semiconductor light emitting diodes comprise a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on the n-type semiconductor layer 253. In this case, the p-type electrode 256 positioned at a lower portion may be electrically connected with the first electrode 220 by the conductive adhesive layer 230, and the n-type electrode 252 positioned at an upper portion may be electrically connected with the second electrode 240 to be described below. The semiconductor light emitting diode 250 has a large advantage in that electrodes may be disposed up and down, so the chip size may be reduced.

Referring to FIG. 8 again, a fluorescent layer 280 may be formed on a surface of the semiconductor light emitting diode 250. For example, the semiconductor light emitting diode 250 is a blue semiconductor light emitting diode 251 that emits blue light (B), and the fluorescent layer 280 for converting the blue light (B) into a color of a sub-pixel may be provided. In this case, the fluorescent layer 280 may be a red fluorescent 281 and a green fluorescent body 282 constituting an individual pixel.

That is, the red fluorescent body 281 that may convert blue light into red light (R) may be stacked on a blue semiconductor light emitting diode at a position where a red sub-pixel is formed, and the green fluorescent body 282 that may convert blue light into green light (G) may be stacked on a blue semiconductor light emitting diode at a position where a green sub-pixel is formed. Further, only a blue semiconductor light emitting diode may be independently used a portion forming a blue sub-pixel. In this case, red (R), green (G), and blue (B) sub-pixels may form one pixel.

However, the present disclosure is not necessarily limited thereto and other structures for implementing blue, green, and red, as described above, in a display to which flip-chip type light emitting diodes are applied may be applied.

According to this embodiment, the second electrodes 240 are disposed between the semiconductor light emitting diodes 250 and electrically connected with the semiconductor light emitting diodes. For example, the semiconductor light emitting diodes 250 may be disposed in a plurality of lines and the second electrodes 240 may be positioned between the lines of the semiconductor light emitting diodes 250.

Since the distance between the semiconductor light emitting diodes 250 that form individual pixels is sufficiently large, the second electrodes 240 may be positioned between the semiconductor light emitting diodes 250.

The second electrode 240 may be formed as an electrode in a bar shape that is long in one direction and may be disposed perpendicular to the first electrode.

Further, the second electrode 240 and the semiconductor light emitting diode 250 may be electrically connected by a connection electrode protruding from the second electrode 240. In more detail, the connection electrode may be the n-type electrode of the semiconductor light emitting diode 250. For example, the n-type electrode is formed as an ohmic electrode for ohmic contact and the second electrode covers at least a portion of the ohmic electrode by printing or depositing. Accordingly, the second electrode 240 and the n-type electrode of the semiconductor light emitting diode 250 may be electrically connected.

According to the figures, the second electrode 240 may be positioned on the conductive adhesive layer 230. Depending on cases, a transparent insulating layer (not shown) including silicon oxide (SiOx), etc may be formed on the substrate 210 on which the semiconductor light emitting diodes 250 are formed. When the second electrode 240 is positioned after the transparent insulating layer is formed, the second electrode 240 is positioned on the transparent insulating layer. Further, the second electrodes 240 may be formed to be spaced apart from each other on the conductive adhesive layer 230 or the transparent insulating layer.

If a transparent electrode such as ITO (Indium Tin Oxide) is used to position the second electrode 240 on the semiconductor light emitting diode 250, there is a problem in that the ITO substance is not bonded well to a semiconductor layer. Accordingly, the present disclosure has the advantage that there is no need for using a transparent electrode such as ITO by positioning the second electrode 240 between the semiconductor light emitting diodes 250. Accordingly, it is possible to improve optical extraction efficiency by using a conductive substance, which is bonded well to an n-type semiconductor layer, as a horizontal electrode without being limited to selection of a transparent material.

According to the figures, a separation wall 290 may be positioned between the semiconductor light emitting diodes 250. That is, the separation wall 290 may be disposed between the vertical semiconductor light emitting diodes 250 to isolate the semiconductor light emitting diodes 250 forming individual pixels. In this case, the separation wall 290 may serve to separate individual sub-pixels and may be formed integrally with the conductive adhesive layer 230. For example, the semiconductor light emitting diodes 250 are inserted in the anisotropic conductive film, the base member of the anisotropic conductive film may form the separation wall.

Further, when the base member of the anisotropic conductive film is black, the separation wall 290 may have a reflective characteristic and the contrast may be increased even without a discrete black insulator.

As another example, a reflective separation wall may be provided as the separation wall 190. The separation wall 290 may comprise a black or white insulator, depending on the object of the display.

If the second electrode 240 is positioned directly on the conductive adhesive layer 230 between the semiconductor light emitting diodes 250, the separation wall 290 may be positioned between each of the semiconductor light emitting diodes 250 and the second electrodes 240. Accordingly, there is an effect that it is possible to configure individual sub-pixels even in a small size using the semiconductor light emitting diodes 250, it is possible to position the second electrode 240 between the semiconductor light emitting diodes 250 because the distance of the semiconductor light emitting diodes 250 is relatively larger, and it is possible to implement a flexible display having HD quality.

Further, according to the figures, a black matrix 291 may be disposed between fluorescent bodies to improve contrast. That is, the black matrix 291 may improve the contrast of light and darkness.

As described above, the semiconductor light emitting diode 250 is positioned on the conductive adhesive layer 230, whereby it configures an individual pixel in the display. Since the semiconductor light emitting diode 250 has excellent luminance, it may constitute an individual sub-pixel even in a small size. Accordingly, a full-color display in which red (R), green (G), and blue (B) sub-pixels form one pixel by semiconductor light emitting diodes may be implemented.

Examples of the display apparatus described above may be a micro-light emitting diode (LED) display to which an LED having a micrometer (μm) size is applied. A manufacturing process of the micro-LED display may comprise lifting chips constituting semiconductor light emitting diodes 150 and 250 on an interposer (not shown), and transferring the chips to substrates 110 and 210 by using the interposer (not shown).

Hereinafter, the semiconductor light emitting diodes 150 and 250 is referred to as an LED chip 250, and the interposer or the substrate is referred to as a chip tray 300.

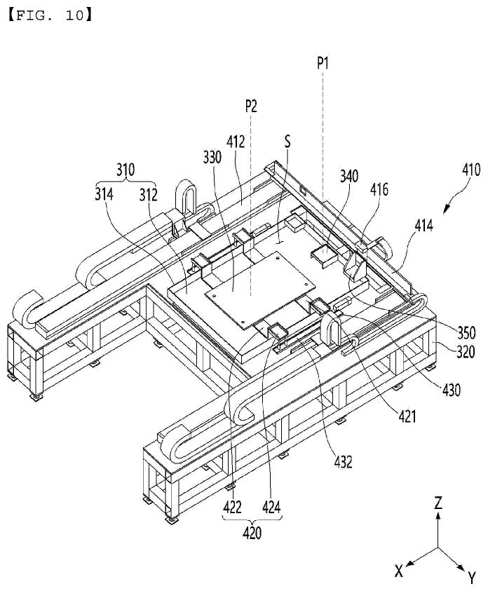

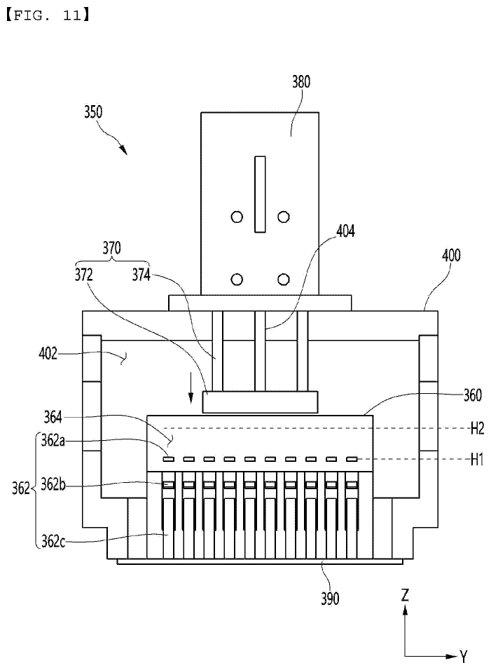

FIG. 10 is a perspective view of a micro-LED display manufacturing apparatus according to the present embodiment, and FIG. 11 is a cross-sectional view illustrating the inside of a magnet head according to the present embodiment.

As shown in FIG. 10, the micro-LED display manufacturing apparatus may comprise a chamber 310 and a table 320.

The chamber 310 may be a chamber for manufacturing a panel. The chamber 310 may be seated on the table 320 and may be located at a predetermined height from the ground.

An upper surface of the chamber 310 may be opened, and the chamber 310 may have a box shape as a whole. The chamber 310 may comprise a lower plate 312 located on the table 310 and an edge portion 314 protruding from an edge of the lower plate 312. A total of four edge portions 314 may be formed, and a space S may be formed inside the four edge portions 314. The space S may be formed above the lower plate 312.

A fluid such as water may be filled in the space S.

A panel (not shown) constituting the micro-LED display may be located on an upper end of the chamber 310 to cover the space S, and the LED chip 250 in the chamber 310 may be assembled to the panel.

As shown in FIG. 10, the micro-LED display manufacturing apparatus may comprise a chip tray 330, a chip bath 340, a magnet head 350, and a head transfer device 410.

The chip tray 330 may be accommodated in the chamber 310. The chip tray 330 may be formed to be smaller than the space S of the chamber 310 and may be located in a partial region of the space S of the chamber 310.

An example of the chip tray 330 may be an interposer that helps the LED chip 250 be transferred to the panel.

The chip bath 340 may accommodate the plurality of LED chips 250 therein. The chip bath 340 may be formed in the chamber 310. The chip bath 340 may have a smaller size than the space S and may be located in the space S. The chip bath 340 may be located apart from the chip tray 330 in the space S of the chamber 310. The chip bath 340 may be located apart from the chip tray 330 in a longitudinal direction of the chamber 310.

The chip bath 340 may be formed adjacent to one of the four edge portions 314 in the chamber 330. The chip bath 340 may be formed by a rib upwardly protruding from the lower plate 312 of the chamber 310 and any one of the four edge portions 314 of the chamber 310.

The magnet head 350 may adsorb and separate the LED chip 250 by magnetic force. The magnet head 350 may be moved from an upper side of the lower plate 312 of the chamber 310. The magnet head 350 may move the LED chip 250 placed on the chip bath 340 to an upper surface of the chip tray 330. The magnet head 350 may be moved to an upper side of the chip bath 340, may then adsorb the LED chip 250 placed on the chip bath 340 by the magnetic force of the magnet 362, may move to an upper side of the chip tray 330, and may then separate the adsorbed LED chip 250 from the magnet head 350.

The magnet head 350 may change a height of the magnet 362 (refer to FIG. 11) and may adsorb or separate the LED chip 250 depending on the height of the magnet 362.

As shown in FIG. 11, when the magnet 362 is lowered to the first height H 1, the LED chip 250 located in the chip bath 340 may be raised by the attractive force of the magnet 362, and when the magnet 362 is raised to the second height H2, the LED chip 250 may be located t from the magnet 362 beyond a distance at which the attractive force of the magnet 362 is applied, and the attractive force of the magnet 362 does not act, and thus the LED chip 250 may fall freely due to gravity.

The first height H1 may be defined as an adsorption height at which the attractive force of the magnet 362 is to be applied to the LED chip 250.

The second height H2 may be higher than the first height H1 in a Z-axis direction Z. The second height H2 may be defined as a separation height at which the attractive force of the magnet 362 does not act on the LED chip 250.

A detailed configuration of the magnet head 350 will be described below.

As shown in FIG. 11, the magnet head 350 may comprise a magnet housing 360, an elevating member 370, a driving source 380, and a glass 390. The magnet head 350 may further comprise a head housing 340.

The magnet housing 360 may accommodate the magnet 362 therein. A magnet space 364 accommodating the magnet 362 therein may be formed in the magnet housing 360.

The plurality of magnets 362 may be located in the magnet housing 360. The plurality of magnets 362 may be located apart from each other in a horizontal direction.

The magnet 362 may comprise a tension magnet 362a, an assembly magnet 362b below the tension magnet 362a, and a pickup magnet 362c below the assembly magnet 362b, and the tension magnet 362a, the assembly magnet 362b, and the pickup magnet 362c may constitute one set.

The elevating member 370 may elevate the magnet housing 360. The elevating member 370 may comprise a fixed body 372 fixed to an upper surface of a magnet housing, and an elevating shaft 374 fixed to an upper surface of the fixed body 372. An upper portion of the elevating shaft 372 may be connected to the driving source 380.

The driving source 380 may elevate the elevating member 370. The driving source 390 may be located on the upper surface of a head housing 400. The driving source 380 may elevate the elevating shaft 374 from an upper portion of the head housing 400.

An elevating space 402 in which the magnet housing 360 is elevated may be formed in the head housing 400. The head housing 400 may protect the magnet housing 360 inside the magnet housing 360. The head housing 400 may be a glass housing to which the glass 390 is fixed.

The LED chip 250 may be adsorbed to and separated from the glass 390. The glass 390 may be located on a lower surface of the head housing 400. The upper surface of the glass 390 may be fixed to a bottom surface of the head housing 400. The bottom surface of the glass 390 may be a contact surface in which the LED chip 250 contacts and is separated.

For hydrophilization, the glass 390 may be, for example, a SiO₂ glass on which SiO₂ is deposited. The glass 390 may be formed of a transparent material, and an elastic layer may be formed on an upper surface of the glass 390.

The glass 390 may be defined as a separation layer between the pickup magnet 362c and the LED chip 250, and the LED chip 250 may be attracted by the attractive force of the pickup magnet 362c to be in contact with the bottom surface of the glass 390.

The space 402 in which the magnet housing 400 and the elevating member 370 are accommodated may be formed in the head housing 400. A through hole 404 through which the elevation shaft 374 of the elevation member 370 passes may be formed at an upper portion of the head housing 400.

As shown in FIG. 10, the head transfer device 410 may transfer the magnet head 350 to a first position P1 of the chip bath 340 and a second position P2 of the chip tray 330. An example of the head transfer device 410 may be a robot.

The head transfer device 410 may comprise an X-axis driver 412, a Y-axis driver 414, and a Z-axis driver 416.

The micro-LED display manufacturing apparatus may further comprise chip tray supporters 420 and 421.

The chip tray supporters 420 and 421 may be located apart from the chip bath 330 in the chamber 310. The plurality of chip tray supporters 420 and 421 may be located in the chamber 310, and the plurality of chip tray supporters 420 and 421 may be located apart from each other. The plurality of chip tray supporters 420 and 421 may be located apart from each other in an X-direction X. The plurality of chip tray supporters 420 and 421 may have the same structure, and hereinafter, for convenience of description, one chip tray supporter 420 will be described.

An accommodation body 422 in which the chip tray 330 is accommodated may be formed on the chip tray supporter 420.

The chip tray supporter 420 may comprise a connection body 424 connected to the accommodation body 422.

The connection body 424 may be located to surround the edge portion 314 of the chamber 310, and may surround an inner surface, an upper end, and an outer surface of the edge portion 314.

The micro-LED display manufacturing apparatus may further comprise a driving device 430.

The driving device 430 may elevate the chip tray supporter 420 in the Z-axis direction or move the chip tray supporter 420 in a longitudinal direction (X-axis direction) of the chamber 310. The driving device 430 may comprise a driving source such as a motor or a cylinder.

The driving device 430 may be connected to the chip tray supporter 420 through a power transmission member 432, and the driving device 430 and the power transmission member 432 may elevate or mote the chip tray supporter 420 in a state of being located outside the chamber 310.

The head transfer device 410 and the driving device 430 may be located on the table 320.

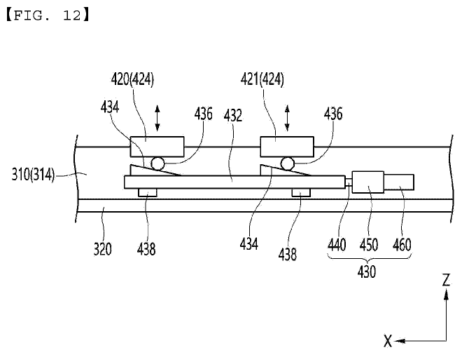

FIG. 12 is a side view showing a driving device according to the present embodiment.

An example of the power transmission member 432 a slider 432 moving forward or backward in the X-axis direction around the edge portion 314 of the chamber 310, and the driving device 430 may be connected to the slider 432. Hereinafter, for convenience of description, the power transmission member and the slider will be described using the same reference numerals.

A gradient portion 434 may be formed on an upper surface of the slider 432, and a contact body 436 such as a roller seated on an upper surface of the gradient portion 434 may be provided at the chip tray supporter 420, in particular, a lower end of the connection body 424.

The gradient portion 434 may protrude from an upper surface of the slider 432, and an inclined surface inclined in an inclined direction with respect to a horizontal surface may be formed on the upper surface of the gradient portion 434.

The slider 432 may function as a cam device, the slider 432 may be a camshaft, and the gradient portion 434 may be a cap protruding from the camshaft.

A linear guide 438 may be provided on a bottom surface of the slider 432. The linear guide 438 may be located on an upper surface of the table 320.

When the slider 432 is moved forward, the chip tray supporter 420 may be lowered, and when the slider 434 is moved rearward, the chip tray supporter 420 may be raised.

An example of the driving device 430 may comprise a forward/backward shaft 440 connected to one end of the slider 432, a cylinder 450 moving the forward/backward shaft 440 forward and rearward, and a motor 460 connected to the cylinder 450. When the driving device 430 moves the slider 432 in a straight line, various examples may be applied.

A screw that is connected to a shaft of the motor 460 and rotated may be embedded in the cylinder 450, and forward/backward member such as a nut linearly guided along the screw may be located in the forward/backward shaft 440.

Another example of the power transmission member 432 may be a slider coupled with the chip tray supporter 420, particularly, the connection body 424, and in this case, when the driving device 430 moves the slider forward and rearward, the tray supporter 420 may be moved forward and rearward along with the slider.

The above-disclosed subject matter is to be considered illustrative, and not restrictive, and the appended claims are intended to cover all such modifications, enhancements, and other embodiments, which fall within the true spirit and scope of the present disclosure.

Thus, the embodiment of the present disclosure is to be considered illustrative, and not restrictive, and the technical spirit of the present disclosure is not limited to the foregoing embodiment.

Therefore, the scope of the present disclosure is defined not by the detailed description of the disclosure but by the appended claims, and all differences within the scope will be construed as being comprised in the present disclosure.

What is claimed:

1. An apparatus for manufacturing a micro light emitting diode (LED) display, the apparatus comprising:
a chip tray accommodated in a chamber;
a chip bath accommodating a plurality of LED chips therein;
a magnet head configured to adsorb/separate the LED chip by magnetic force; and
a head transfer device configured to move the magnet head to a first position of the chip bath and a second position of the chip tray,
wherein the magnet head comprises:
a magnet housing accommodating a magnet therein;
an elevating member configured to elevate the magnet housing;
a driving source configured to elevate the elevating member; and
a glass to and from which the LED chip is adsorbed and separated.

2. The apparatus of claim 1, wherein the magnet head comprises a head housing with a space formed therein to accommodate the magnet housing and the elevating member are accommodated, and
the glass is located on a lower surface of the head housing.

3. The apparatus of claim 2, wherein the driving source is located on an upper surface of the head housing.

4. The apparatus of claim 2, wherein the elevating member comprises:
a fixed body fixed to an upper surface of the magnet housing; and
an elevating shaft fixed to an upper surface of the fixed body, and
the head housing comprises a through hole formed therein through which the elevating shaft passes.

5. The apparatus of claim 1, wherein the chip bath is formed in the chamber.

6. The apparatus of claim 1, further comprising a chip tray supporter located apart from the chip bath in the chamber and having an accommodation body formed therein to accommodate the chip tray.

7. The apparatus of claim 6, wherein the chip tray supporter comprises a connection body connected to the accommodation body, and
the connection body surrounds an inner lateral surface, an upper end, and an outer lateral surface of an edge of the chamber.

8. The apparatus of claim 6, wherein a plurality of chip tray supporters are located apart from each other.

9. The apparatus of claim 1, further comprising a driving device configured to move the chip tray supporter in a longitudinal direction of the chamber.

10. The apparatus of claim 9, further comprising a table on which the chamber is seated,
wherein the driving device and the head transfer device are located on the table.
